(19) United States
(12) Patent Application Publication
(10) Pub. No.: US 2008/0094087 A1
(43) Pub. Date: Apr. 24, 2008

(54) Device for detecting chip location and method of detecting chip location using the device

(75) Inventor: Ho-jin Lee, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/827,689

(22) Filed: Jul. 13, 2007

(30) Foreign Application Priority Data
Oct. 20, 2006 (KR) 10-2006-0102472

(51) Int. Cl. G01R 31/02; G01J 5/00

(52) U.S. Cl. 324/756; 250/330

(57) ABSTRACT

In a device for detecting a chip location and a method of detecting a chip location using the device, the device includes a chuck to which a wafer to be inspected is fixable, an infrared irradiation unit capable of irradiating infrared light to a target semiconductor chip of the wafer from the backside of the wafer, and a scope disposed opposite to the infrared irradiation unit with respect to the wafer. In this manner, it can be readily be determined whether the scope is aligned with a target semiconductor chip to which a probe card is connected for inspection by a backside emission method. Furthermore, the target semiconductor chip to be inspected can be readily detected among semiconductor chips viewed through the scope. Therefore, TAT (turn around time) for inspection can be largely reduced.

### CROSS-REFERENCE TO RELATED PATENT APPLICATION

This application claims priority under 35 U.S.C. 119 to Korean Patent Application No. 10-2006-0102472, filed on Oct. 20, 2006, in the Korean Intellectual Property Office, the disclosure of which is incorporated herein in its entirety by reference.

### BACKGROUND OF THE INVENTION

1. Field of the Invention

The present invention relates to a device for detecting a chip location and a method of detecting a chip location using the device, and more particularly, to a device for determining whether a scope is properly aligned with a semiconductor chip to which a probe card is attached for inspection by a backside emission analysis method and detecting the location of a target semiconductor chip among semiconductor chips viewed through the scope, and a method of detecting the location of a semiconductor chip using the device.

2. Description of the Related Art

Backside emission analysis is used as a method of inspecting semiconductor chips formed on a wafer. FIG. 1 is a schematic view for illustrating the backside emission method. Referring to FIG. 1, a wafer 10 is fixed to a chuck 30 for inspection. The wafer 10 can be fixed to the chuck 30 by creating a vacuum along a vacuum groove 33 formed in a surface of the chuck 30 to which the wafer 10 is placed. Here, the wafer 10 is placed on the chuck 30 such that the front side of the wafer 10, where semiconductor chips are formed, is oriented in a downward direction, and the backside of the wafer 10 is oriented in an upward direction.

Thereafter, needles 25 of a probe card 20 are brought into contact with pads 15 of a target semiconductor chip 13 of the wafer 10. This process is manually performed for a relatively long time (about 30 minutes). Then, a scope 40 is placed above the target semiconductor chip 13 and aligned with the target semiconductor chip 13, and then a voltage is supplied to the target semiconductor chip 13. As a result, photons (hf) are generated at a defective point of the target semiconductor chip 13. Therefore, when photons are observed through the scope 40, it can be determined that the target semiconductor chip 13 has a defective point. An example of such a defective point can be seen in the example of FIG. 2. On the other hand, when photons hf are not observed through the scope 40, it can be determined that the target semiconductor chip 13 has no defective point.

In the conventional process, the scope 40 is aligned with the target semiconductor chip 13 depending on the memory of a human operator. That is, after finding the location of the target semiconductor chip 13 based on operator's memory about the row and column of the wafer 10 to which the target semiconductor chip 13 belongs, the needles 25 of the probe card 20 are brought into contact with the target semiconductor chip 13, and the scope 40 is placed above the backside of the wafer 10 and aligned with the target semiconductor chip 13.

Therefore, when the memory of an operator is not correct, a semiconductor chip other than the target semiconductor chip 13 can be observed through the scope 40 as shown in FIG. 3. In this case, for example, although photons are generated from the target semiconductor chip 13 since the semiconductor chip 13 is defective, photons cannot be observed through the scope 40, and thus, in this situation, it can be erroneously determined that the target semiconductor chip 13 is not defective.

Furthermore, when an operator realizes that his/her memory is not correct, the operator should repeat the above-mentioned setup procedures for inspection. However, since it takes much time for contacting the needles 25 of the probe card 20 to the target semiconductor chip 13, the turn around time (TAT) of semiconductor chip inspection necessarily increases.

The backside emission analysis method is used for inspecting semiconductor chips formed on a wafer since, as the integration level of a semiconductor chip increases, most defective transistors are formed close to the backside of the wafer; however, metal lines formed on the front side of the wafer block visibility of the defects. That is, when semiconductor chips formed on a wafer is inspected by an emission method in which the front side of the wafer is oriented in an upward direction, photons generated from a defective transistor formed close to a lower portion of the wafer cannot be observed since the photons are blocked by metal lines formed on the front side of the wafer.

### SUMMARY OF THE INVENTION

Embodiments of the present invention provide a device for determining whether a scope is properly aligned with a semiconductor chip to which a probe card is attached for inspection by a backside emission analysis method and detecting the location of a target semiconductor chip among semiconductor chips viewed through the scope.

Embodiments of the present invention also provide a method of detecting a chip location using the device.

In one aspect, a device for detecting a chip location includes: a chuck to which a wafer to be inspected can be mounted; an infrared irradiation unit capable of irradiating infrared light to a target semiconductor chip of the wafer from the backside of the wafer; and a scope disposed opposite the infrared irradiation unit with respect to the wafer.

In the device, the location of a target semiconductor chip to be inspected can be precisely detected using infrared laser light passing through the target semiconductor chip. Therefore, inspection errors caused by faulty information about chip location can be reduced, and a target semiconductor chip can be located quickly. As a result, turn around time (TAT) required for inspection can be largely reduced.

The infrared light irradiated from the infrared irradiation unit may have a predetermined wavelength such that the infrared light passes through the wafer. Particularly, the infrared light irradiated from the infrared irradiation unit may have a wavelength of about 1100 nm to about 1300 nm.

The device may further include a backside visualization unit that determines whether the infrared irradiation unit is aimed at the target semiconductor chip of the wafer to be inspected. Thus, the infrared irradiation unit can be aligned more precisely and conveniently by using the backside visualization unit.

The device may further include a probe card including an opening and a needle positioned about the opening configured to be electrically connected to a pad of the target semiconductor chip to be inspected. Here, the infrared irradiation unit may irradiate infrared light to the target semiconductor chip through the opening. In this case, the infrared light can be more precisely irradiated to the target semiconductor chip at a right angle, and thus the infrared light can be readily transmitted through the target semiconductor chip.

The backside visualization unit may be used for determining whether the needle is connected to the pad of the target semiconductor chip. In this case, the needle of the probe card can be more readily connected to the pad of the target semiconductor chip using the backside visualization unit.

In another aspect, a method of detecting a chip location includes: mounting a wafer to be inspected on a chuck; aiming an infrared irradiation unit at a target semiconductor chip of the wafer; irradiating infrared light from the infrared irradiation unit to the target semiconductor chip; and aligning a scope with the target semiconductor chip so that the infrared light transmitted through the target semiconductor chip is viewed through the scope.

The method may further include: providing a probe card including an opening and a needle positioned about the opening configured to be electrically connected to a pad of the target semiconductor chip; and contacting the needle to the pad of the target semiconductor chip to be inspected.

The aiming of the infrared irradiation unit may include aiming the infrared irradiation unit to the target semiconductor chip through the opening of the probe card.

The contacting of the needle may be performed using a backside visualization unit

The aiming of the infrared irradiation unit to the target semiconductor chip through the opening of the probe card may be performed using the backside visualization unit.

In this case, the contacting of the needle and the aiming of the infrared irradiation unit can be performed more precisely and conveniently by using the backside visualization unit.

The aligning of the scope may include: changing a relative position between the scope and the wafer until a semiconductor chip through which infrared light passes is viewed through the scope; and determining that the semiconductor chip is the target semiconductor chip.

In the method, the location of a target semiconductor chip to be inspected can be precisely detected using infrared laser light passing through the target semiconductor chip. Therefore, inspection errors caused by faulty information about chip location can be reduced, and the time for location of a target semiconductor chip can be reduced. As a result, TAT required for inspection can be largely reduced.

### BRIEF DESCRIPTION OF THE DRAWINGS

The above and other features and advantages of the embodiments of the present specification will become more apparent by describing in detail exemplary embodiments thereof with reference to the attached drawings in which:

FIG. 1 is side sectional view for schematically illustrating a backside emission analysis method;

FIG. 2 is an example scope image of photons emitted from a defective point by a backside emission analysis method;

FIG. 3 is a side sectional view illustrating a misaligned scope when a conventional backside emission analysis is performed;

FIG. 4 is a side sectional view illustrating a device for detecting a chip location according to an embodiment of the present invention;

FIG. 5 is a side sectional view illustrating a device for detecting a chip location according to another embodiment of the present invention; and

FIG. 6 is an image for explaining how a particular semiconductor chip is detected by passing infrared laser light through a wafer using a chip location detection device according to an embodiment of the present invention.

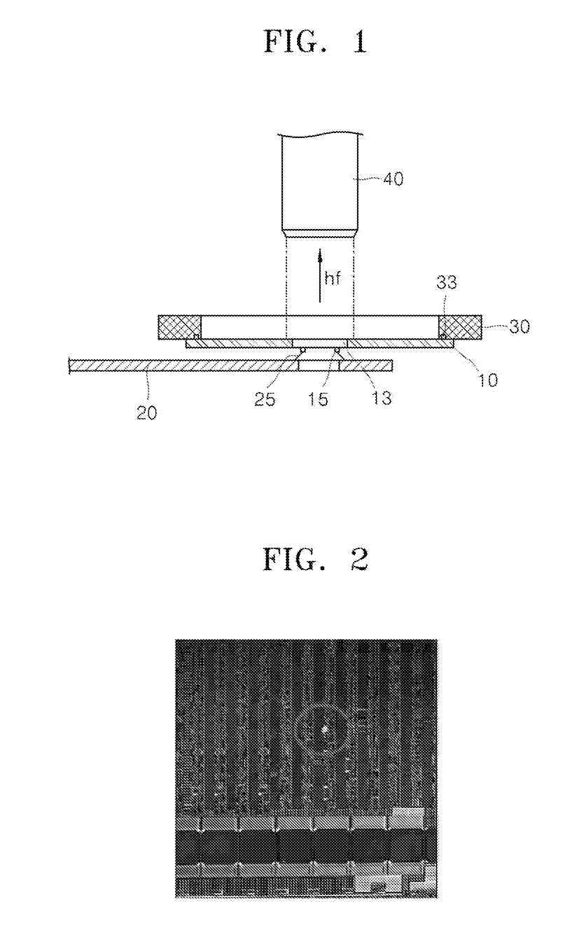

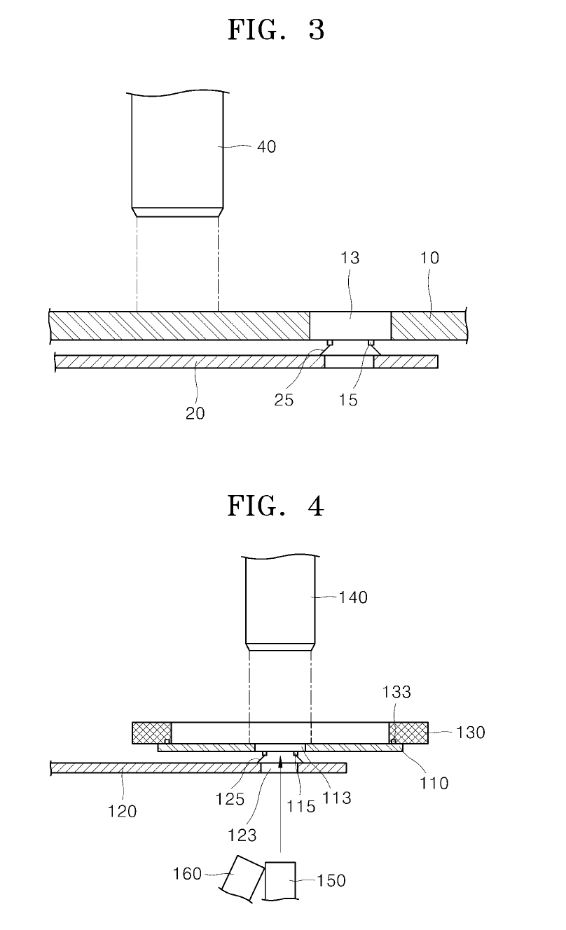

### DETAILED DESCRIPTION OF EMBODIMENTS

Embodiments of the present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete. In the drawings, like reference numerals in the drawings denote like elements, and elements and regions are schematically drawn.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In one aspect, there is provided a device for detecting a chip location. The device includes: a chuck to which a wafer to be inspected is fixable; an infrared irradiation unit capable of irradiating infrared light to a target semiconductor chip of the wafer from the backside of the wafer; and a scope disposed opposite to the infrared irradiation unit with respect to the wafer. FIG. 4 is a side sectional view illustrating a device for detecting a chip location according to an embodiment of the present invention.

Referring to FIG. 4, the chip location detection device of the current embodiment includes a chuck 130 to which a wafer 110 to be inspected can be fixed with the backside of the wafer 110 facing in an upward direction. Alternatively, the chuck 130 can be formed with a vacuum groove 133 in which a vacuum can be created for fixing the wafer 110 on the chuck 130.

The chip location detection device further includes an infrared irradiation unit 150 that can irradiate a target semiconductor chip 113 of the wafer 110 with infrared laser light from the bottom of the chip location detection device. The infrared irradiation unit 150 irradiates infrared laser light having a predetermined wavelength such that the infrared laser beam can pass through the wafer 110. For example, the infrared irradiation unit 150 irradiates infrared laser light having a wavelength of about 1100 nm to about 1300 nm. At these wavelengths, the infrared laser light can pass through a wafer.

A scope 140 can be disposed opposite to the infrared irradiation unit 150 with respect to the wafer 110. Since the wavelength of the infrared laser light irradiated from the infrared irradiation unit 150 is out of the wavelength range of visible light, it is difficult to observe the infrared laser light with the naked eye. However, the infrared laser light can be observed with the naked eye using the scope 140. Furthermore, when the target semiconductor chip 113 is inspected after the location of the target semiconductor chip 113 is detected using the chip location detection device, photons generated from the target semiconductor chip 113 can be detected using the scope 140. A scope of the type used in a conventional analyzer using an emission analysis method can be employed as the scope 140.

In the chip location detection device, infrared laser light irradiated from the infrared irradiation unit 150 can reach the scope 140 through the wafer 110. Thus, a semiconductor chip at which an infrared spot is observed using the scope 140 can be determined as the target semiconductor chip 113 to be inspected.

The chip location detection device can optionally further include a backside visualization unit 160 for determining whether the infrared irradiation unit 150 is aimed at the target semiconductor chip 113. For example, the backside visualization unit 160 may be a charge coupled device (CCD) camera. However, the backside visualization unit 160 is not limited to the CCD camera. Alternatively, the backside visualization unit 160 may synchronously move with the infrared irradiation unit 150.

The chip location detection device of the current embodiment can optionally further include a probe card 120. The probe card 120 includes an opening 123 and needles 125 around the opening 123. The needles 125 can be electrically connected to pads 115 of the target semiconductor chip 113 of the wafer 110. A conventional probe card can be used as the probe card 120. Infrared laser light emitted from the infrared irradiation unit 150 may be irradiated to the target semiconductor chip 113 through the opening 123 of the probe card 120.

Alternatively, the backside visualization unit 160 can be used to determine whether the needles 125 make contact with the pads 115 of the target semiconductor chip 113. In this case, the backside visualization unit 160 is used to determine whether the infrared irradiation unit 150 is properly aimed at the target semiconductor chip 113 and whether the needles 125 contact the pads 115.

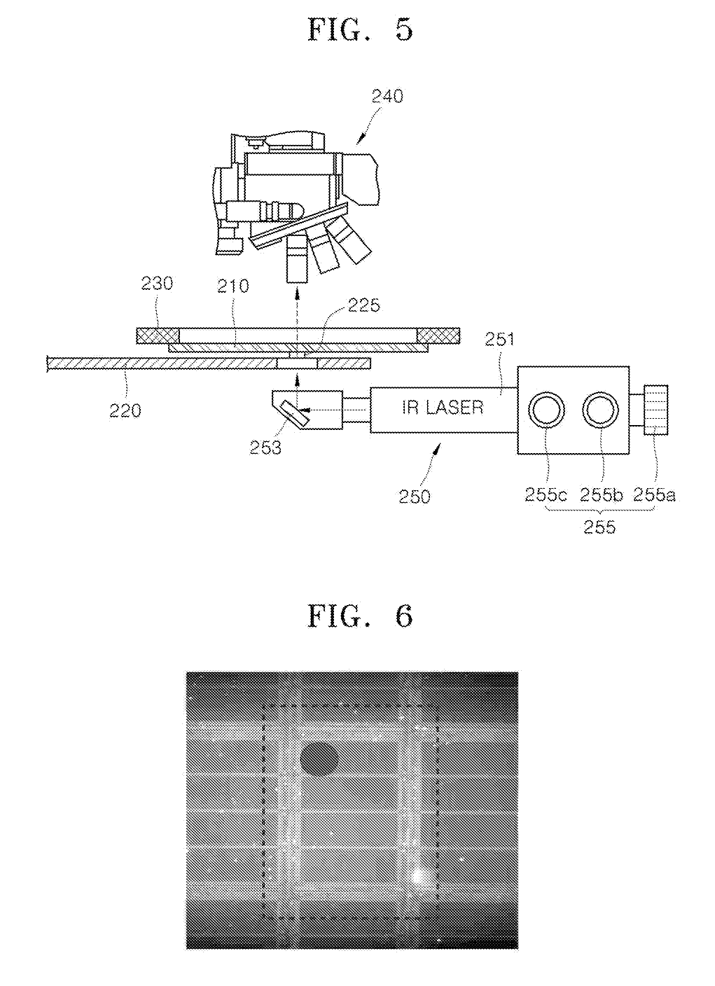

FIG. 5 is a side sectional view illustrating a device for detecting a chip location according to another embodiment of the present invention. A chuck 230, a wafer 210, and a probe card 220 have the same structures as those of the previous embodiment. An infrared irradiation unit 250 may include an infrared laser generation unit 251 emitting infrared laser light in a horizontal direction and a reflection mirror 253 reflecting the laser light in a vertical direction. The position of the infrared irradiation unit 250 can be adjusted about an x-axis, a y-axis, and a z-axis using knobs 255a, 255b, and 255c. A scope 240 is disposed opposite to the infrared irradiation unit 250 with respect to the wafer 210. Infrared laser light passing through the wafer 210 can be observed with the naked eye using the scope 240.

In another aspect, there is provided a method of detecting a chip location. The method includes: mounting a wafer to be inspected on a chuck; aiming an infrared irradiation unit at a target semiconductor chip of the wafer; irradiating infrared light from the infrared irradiation unit to the target semiconductor chip; and aligning a scope with the target semiconductor chip so that the infrared light transmitted through the target semiconductor chip is viewed through the scope.

Referring again to FIG. 4, the wafer 110 is mounted on the chuck 130. As described above, the chuck 130 may include the vacuum groove 133 for fixing the wafer 110. When the wafer 110 is mounted on the chuck 130, the backside of the wafer 110 may face in an upward direction.

The infrared irradiation unit 150 is disposed under the wafer 110 and aimed at the target semiconductor chip 113 of the wafer 110 to be inspected. The infrared irradiation unit 150 is aimed at the target semiconductor chip 113 so that the infrared irradiation unit 150 can irradiate infrared laser light to any point of the target semiconductor chip 113. In this case, the aiming of the infrared irradiation unit 150 is performed manually. Here, the backside visualization unit 160 can be used to facilitate the aiming of the infrared irradiation unit 150 as described above.

Alternatively, the probe card 120, which includes the opening 123 and the needles 125 around the opening 123, can be prepared, and the needles 125 can be connected to the pads 115 of the target semiconductor chip 113 of the wafer 110.

As described above, a conventional probe card can be used as the probe card 120. Furthermore, the needles 125 of the probe card 120 can be connected to the pads 115 of the target semiconductor chip 113 using the backside visualization unit 160. For example, the backside visualization unit 160 can be in the form of a CCD camera. In this case, the infrared irradiation unit 150 can be aimed at the target semiconductor chip 113 using images obtained by the CCD camera and displayed on a display device.

Alternatively, the infrared irradiation unit 150 can be aimed at the target semiconductor chip 113 through the opening 123 of the probe card 120. In this case, infrared laser light emitted from the infrared irradiation unit 150 can be readily irradiated to a center portion of the target semiconductor chip 113 at a right angle. Alternatively, the infrared irradiation unit 150 can be aimed at the target semiconductor chip 113 through the opening 123 of the probe card 120 using the backside visualization unit 160. As described above, the backside visualization unit 160 may be a CCD camera. In this case, the infrared irradiation unit 150 can be aimed at the target semiconductor chip 113 through the opening 123 of the probe card 120 by using images obtained by the CCD camera and displayed on a display device.

Thereafter, the infrared irradiation unit 150 irradiates infrared laser light to the wafer 110. The infrared laser light passes through the wafer 110. In this manner, it can be determined which semiconductor chip is a target semiconductor chip 113 to be inspected by aligning the scope 140 to a semiconductor chip from which an infrared spot is observed. If an infrared spot (refer to FIG. 6) cannot be observed through the scope 140 although infrared laser light is irradiated to the wafer 110, then it can be concluded that the scope 140 is not properly aligned with the target semiconductor chip 113. In this case, the scope 140 is moved relative to the wafer 110 until an infrared spot is observed. In other words, the scope 140 is moved relative to the wafer 110 until a semiconductor chip on which an infrared spot is formed is observed through the scope 140, and then the semiconductor chip is determined as the target semiconductor chip 113 to be inspected. In this way, the location of a target semiconductor chip can be detected.

Following proper detection of the location of a target, the infrared irradiation unit 150 may stop radiation, and then the target semiconductor chip 113 is inspected for defects by supplying a voltage to the target semiconductor chip 113 through the probe card 120. In this way, semiconductor chips of the wafer 110 can be inspected by the backside emission analysis method.

According to the device for detecting the location of a chip and a method of detecting the location of a chip using the device of the embodiments of the present specification, it can be readily determined whether the scope is aligned with a target semiconductor chip to which the probe card is connected for inspection by the backside emission method. Furthermore, a target semiconductor chip to be inspected can be readily located among semiconductor chips viewed through the scope. Therefore, TAT (turn around time) for inspection can be largely reduced.

While embodiments of the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A device for detecting a chip location, comprising:
a chuck to which a wafer to be inspected can be mounted;
an infrared irradiation unit capable of irradiating infrared light to a target semiconductor chip of the wafer from the backside of the wafer; and
a scope disposed opposite the infrared irradiation unit with respect to the wafer.

2. The device of claim 1, wherein the infrared light irradiated from the infrared irradiation unit has a wavelength of about 1100 nm to about 1300 nm.

3. The device of claim 1, wherein the infrared light irradiated from the infrared irradiation unit has a predetermined wavelength such that the infrared light passes through the wafer.

4. The device of claim 1, further comprising a backside visualization unit that determines whether the infrared irradiation unit is aimed at the target semiconductor chip of the wafer to be inspected.

5. The device of claim 1, further comprising a probe card including an opening and a needle positioned about the opening configured to be electrically connected to a pad of the target semiconductor chip to be inspected, wherein the infrared irradiation unit irradiates infrared light to the target semiconductor chip through the opening.

6. The device of claim 5, further comprising a backside visualization unit that determines whether the needle is connected to the pad of the target semiconductor chip.

7. A method of detecting a chip location, comprising:
mounting a wafer to be inspected on a chuck;
aiming an infrared irradiation unit at a target semiconductor chip of the wafer;
irradiating infrared light from the infrared irradiation unit to the target semiconductor chip; and
aligning a scope with the target semiconductor chip so that the infrared light transmitted through the target semiconductor chip is viewed through the scope.

8. The method of claim 7, the method further comprising:
providing a probe card including an opening and a needle positioned about the opening configured to be electrically connected to a pad of the target semiconductor chip; and
contacting the needle to the pad of the target semiconductor chip to be inspected.

9. The method of claim 8, wherein the aiming of the infrared irradiation unit comprises aiming the infrared irradiation unit to the target semiconductor chip through the opening of the probe card.

10. The method of claim 9, wherein the aiming of the infrared irradiation unit to the target semiconductor chip through the opening of the probe card is performed using a backside visualization unit.

11. The method of claim 8, wherein the contacting of the needle is performed using a backside visualization unit.

12. The method of claim 7, wherein the aligning of the scope comprises:
changing a relative position between the scope and the wafer until a semiconductor chip through which infrared light passes is viewed through the scope; and
determining that the semiconductor chip is the target semiconductor chip.
